(19) United States
(12) Patent Application Publication
(10) Pub. No.: US 2023/0197866 A1
(43) Pub. Date: Jun. 22, 2023

(54) ELECTRON-PHOTON BARRIER IN PHOTODETECTORS

(71) Applicant: Attollo Engineering, LLC, Camarillo, CA (US)

(72) Inventors: Bora Onat, Camarillo, CA (US); Edward K. Huang, Newbury Park, CA (US)

(21) Appl. No.: 17/553,212

(22) Filed: Dec. 16, 2021

(51) Int. Cl. H01L 31/0232; H01L 31/109; H01L 31/0304; H01L 27/146

(52) U.S. Cl. CPC H01L 31/02327; H01L 31/109; H01L 31/03046; H01L 27/14627

(57) ABSTRACT

A dual band photodetector includes a first band absorber layer is configured to absorb incident light in a first wavelength spectral band and a second band absorber layer configured to absorb incident light in a second wavelength spectral band. The dual band photodetector further includes an electron-photon blocking (EPB) layer located between the respective layers and includes at least one high band gap layer and at least one intervening layer. The difference in refractive index between the at least one high band gap layer and the at least one intervening layer form a distributed brag reflector (DBR) designed to reflect wavelengths corresponding with radiative recombination photons emitted from at least the first absorber layer to reduce optical crosstalk between the first band absorber layer and the second band absorber layer.

### TECHNICAL FIELD

The invention relates generally to photodetectors and in particular to an electron-photon barrier layer utilized in single band and dual band photodetectors.

### BACKGROUND

A photodetector is a device that detects or responds to incident light by using the electrical effect of absorbed individual photons. Photodetectors may be designed to detect incident light within a particular spectral frequency range (e.g., visible, infrared, etc.).

A dual band photodetector is one that is capable of operating in a first mode to detect light in a first spectral range and a second mode to detect light in a second spectral range. Typically, a first absorber layer (i.e., Band 1 region) is reverse biased to detect photons absorbed in a first spectral range and a second absorber layer (i.e., Band 2 region) is reverse biased to detect photons absorbed in a second spectral range, wherein a minority-majority carrier pair is created in response to absorption of a photon (light) within the given spectral range. The barrier layer blocks majority carriers from propagating between the respective absorber layers (e.g., the barrier layer blocks electrons in nBn detectors and holes in pBp detectors). The reverse biasing of the corresponding absorber layer allows the minority carrier to be collected which is proportional to the number of photons absorbed. In the first mode, minority carriers are collected from the first absorber layer, and in the second mode minority carriers are collected from the second absorber layer. A blocking layer comprised of high band gap layer is typically positioned between the first absorber layer and the second absorber layer to block majority carrier transport between the respective absorption layers. The blocking layer ensures that minority carriers collected during a first mode originated in the first absorber layer and minority carriers collected during a second mode originated in the second absorber layer, thereby preventing (or at least reducing) crosstalk between the respective absorber layers.

Typical blocking layers only block majority carriers (e.g., electrons in nBn detectors or holes in pBp detectors). In dual band photodetectors, when imaging in the higher spectral range (e.g., detecting light absorbed by second absorber layer), light may be generated in the other region (i.e., first absorber layer) via radiative recombination. In some cases, the wavelength of the light generated via radiative recombination in the first absorber layer may propagate and be absorbed in the second absorber layer, resulting in undesirable crosstalk between the respective bands or layers. It would therefore be desirable to prevent or reduce this type of optical crosstalk between respective bands.

### SUMMARY

According to one aspect, a dual band photodetector includes a first band absorber layer configured to absorb incident light in a first wavelength spectral band and a second band absorber layer configured to absorb incident light in a second wavelength spectral band. The dual band photodetector further includes an electron-photon blocking (EPB) layer located between the respective layers and includes at least one high band gap layer and at least one intervening layer. The difference in refractive index between the at least one high band gap layer and the at least one intervening layer form a distributed brag reflector (DBR) designed to reflect wavelengths corresponding with radiative recombination photons emitted from at least the first absorber layer to reduce optical crosstalk between the first band absorber layer and the second band absorber layer.

According to another aspect, a photodetector includes a first band absorber layer configured to absorb incident light in a first wavelength spectral band and an electron-photon blocking (EPB) layer located adjacent to the first band absorber layer. The EPB layer includes at least one high band gap layer having a first refractive index and at least one intervening layer having a second refractive index different than the first refractive index, wherein a difference in refractive index between the at least one high band gap layer and the at least one intervening layer form a distributed brag reflector (DBR) designed to reflect a wavelength or subset of wavelengths within the first wavelength spectral band.

According to another aspect, a dual band imaging device includes an imaging lens, a readout integrated circuit (ROIC), and a dual band photodetector. The dual band photodetector includes a plurality of dual band pixels configured to receive incident light from the imaging lens and to generate an electrical response, each pixel comprising a first band absorber layer, a second band absorber layer, and an electron-photon blocking (EPB) layer located between the first band absorber layer and the second band absorber layer. The EPB layer includes at least one high band gap layer and at least one intervening layer, wherein the high band gap layer is configured to block majority carrier transport between the first band absorber layer and the second band absorber layer and a difference in refractive index between the at least one high band gap layer and the at least one intervening layer form a distributed brag reflector (DBR) designed to reflect wavelengths corresponding with radiative recombination photons emitted from at least the first absorber layer to reduce optical crosstalk between the first band absorber layer and the second band absorber layer.

### BRIEF DESCRIPTION OF THE DRAWINGS

FIG. 1 is a block diagram of a dual band imaging system according to some embodiments.

FIG. 2A is a cross-sectional view of a dual band photodetector and FIG. 2B is an energy band diagram corresponding with the dual band imaging device according to some embodiments.

FIG. 3 is a graph illustrating the reflectivity of the electron-photon blocking (EPB) according to some embodiments.

FIG. 4 is a cross-sectional view of a single band photodetector according to some embodiments.

### DETAILED DESCRIPTION

According to some aspects, the present disclosure is directed to photodetectors, and in particular to photodetectors utilizing an electron-photon blocking (EPB) layer. In some embodiments, the EPB layer is comprised of one or more alternating stacks of high band gap layers defined by a first refractive index separated by an intervening layer having a second refractive index different than the first refractive index. In some embodiments, the first refractive index of the high band gap layer is less than the second refractive index associated with the intervening layer. The contrast in refractive indexes between the respective layers of the EPB create a distributed brag reflector (DBR). In a dual band detector having a first band region (configured to detect light in a first spectral band range) and a second band region (configured to detect light in a second spectral band range), the EPB layer is located between the first band region and the second band region. The high band gap material included in the EPB layer blocks majority carriers (e.g., electrons, holes depending on the detector type) from propagating between the respective bands, while the DBR acts to reflect light generated as a result of radiative recombination. The EPB layer therefore acts as both an electron blocking layer (i.e., majority carrier) as a well a photon blocking layer that reduces optical crosstalk between the respective detectors. The forward biasing of the respective band by the ROIC causes photogenerated minority carriers from being collected while the other respective band is reverse biased.

According to another aspect, the EPB layer may be utilized in a single band photodetector. The EPB layer may be utilized to reflect unabsorbed light to increase absorption efficiency by the absorption layer (in this case, a single absorption layer). In some embodiments, the increased efficiency may allow for the thickness of the absorption layer to be decreased.

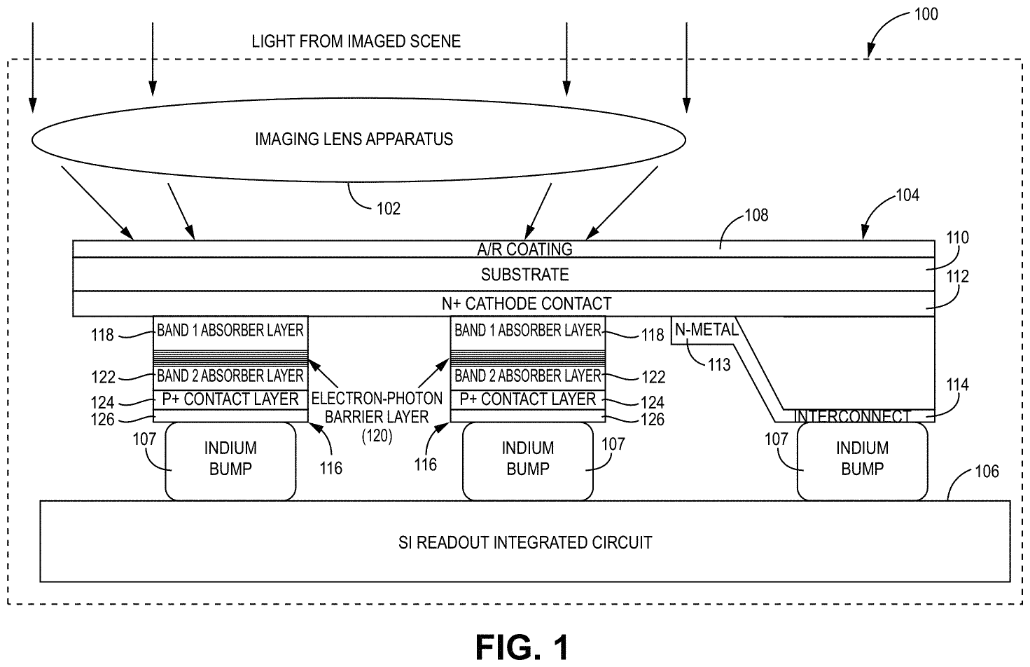

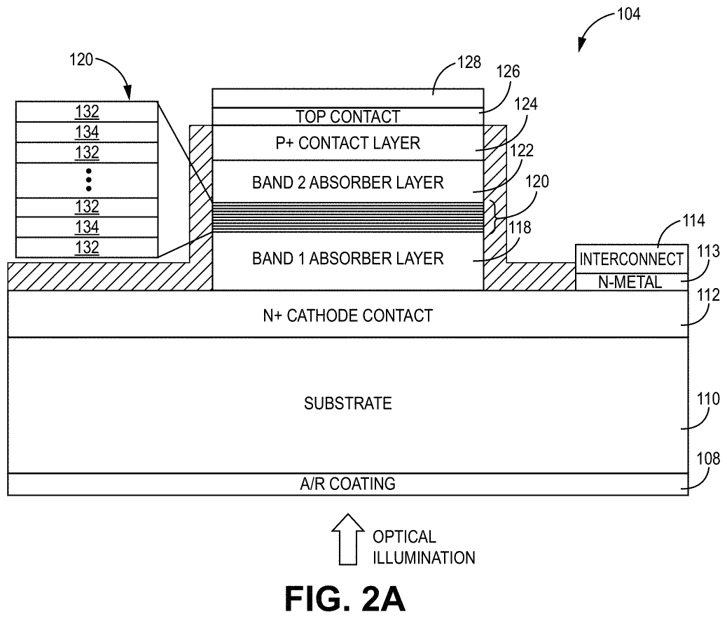

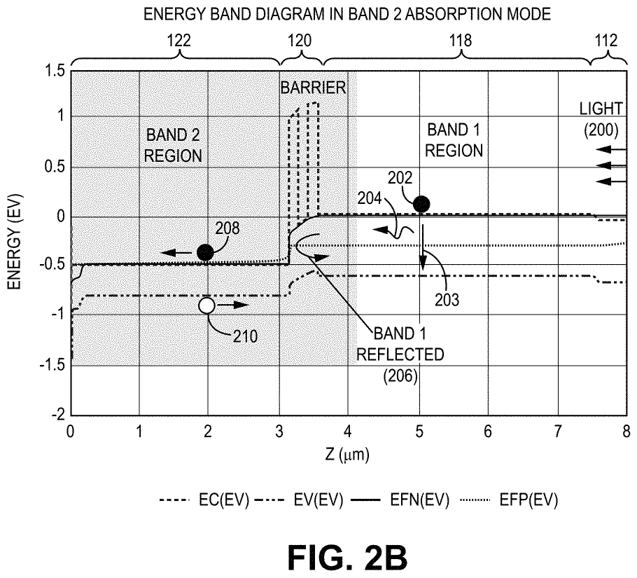

FIG. 1 is a block diagram of a dual band imaging system 100 according to some embodiments. The dual band imaging system 100 includes an imaging lens 102, a dual band photodetector 104 and a readout integrated circuit (ROIC) 106. In general, light incident on the dual band imaging system 100 is focused by the imaging lens 102 onto the dual band photodetector 104. In the embodiment shown in FIG. 1, the dual band photodetector 104 is a backside illuminated detector comprising an anti-reflective coating layer 108, a substrate 110, a cathode contact layer 112, and a plurality of dual band pixels 116 (described in more detail with respect to FIG. 2A). Each dual band pixel 116 is connected to ROIC 106 to collect photo-generated minority carriers (e.g., electrons or holes) generated in response to absorption of light within a desired spectral range.

Each of the plurality of dual band pixels 116 includes first band absorber layer 118, an electron-proton blocking (EPB) layer 120, a second band absorber layer 122, a contact layer 124 and metal contact pad 126. In some embodiments, the first absorber layer 118 is configured to absorb light within a first spectral band and the second absorber layer 122 is configured to absorb light within a second spectral band. In some embodiments, the first spectral band is lower in wavelength than the second spectral band (i.e., the first band absorber layer 118 absorbs higher energy light than the second band absorber layer 122). In this way, incident light in the first spectral band propagates through the anti-reflective coating layer 108 and the substrate 110 and is absorbed by the first band absorber layer 118. Incident light in the second spectral band propagates through the anti-reflective coating layer 108, the substrate 110, the first band absorber layer 118 and the EPB layer 120 and is absorbed by the second band absorber layer 122. Because the incident light in the second spectral band is lower energy (i.e., higher wavelength), the incident light in the second spectral band is not absorbed by the first band absorber layer 118, but instead passes through the first band absorber layer 118 and the EPB layer 120 and is absorbed by the second band absorber layer 122. The energy gained through the absorption of light—whether in the first band absorber layer 118 or second band absorber layer 122—generates an electron-hole pair with an electron moving from the valence band to the conduction band. Minority carriers (either electrons or holes) are collected based on the mode of operation of the device. The dual band photodetector collects these minority carriers (e.g., electrons or holes) from either the first band absorber layer 118 or the second band absorber layer 122, allowing the photodetector to image in either the first spectral band in a first mode of operation or the second spectral band during a second mode of operation. Operation within the first mode or second mode is a result of the polarity of the bias direction. In the first mode, the polarity of the bias voltage set by the ROIC 106 results in the collection of minority carriers created in the first band absorber layer 118. In the second mode, the polarity of the bias voltage is reversed by the ROIC 106 and the minority carriers are collected from the second band absorber layer 122. As discussed in more detail with respect to FIG. 2, the EPB layer 120 acts to prevent the transport of majority carriers between the first band absorber layer 118 and the second band absorber layer 122 to ensure that only minority carriers collected during the first mode are collected only from the first band absorber layer 118 and that minority carriers collected during the second mode are collected only from the second band absorber layer 122. In addition, the distributed Bragg-reflector (DBR) created as a result of changes in refractive index of the various layers acts to reflect photons emitted as a result of radiative recombination, thereby preventing optical crosstalk between the respective absorber layers. In some embodiments, the DBR is designed specifically to reflect light generated through radiative recombination within one of the respective absorber layers, thereby preventing the generated photon from propagating to the other absorber layer and being absorbed and collected, resulting in an erroneous detection of a photon. Typically, this type of optical crosstalk occurs when operating the dual band photodetector to detect light in the higher wavelength spectral band, with radiative recombination occurring in the band absorber layer associated with the lower wavelength spectral band propagating across the barrier layer and being improperly absorbed. In some embodiments, because the bandgap of the absorber layer generating the undesirable radiative recombination is known (e.g., first band absorber layer 118), the DBR is designed to reflect wavelengths of light corresponding with the wavelengths of photons generated via radiative recombination. In some embodiments, the wavelength of the photons generated via radiative recombination is related to the band gap of the absorber layer in which the radiative recombination occurs. Based on knowledge of the bandgap responsible for the radiative recombination, the DBR can be designed based on knowledge of the bandgap and the resulting wavelength of light generated via radiative recombination.

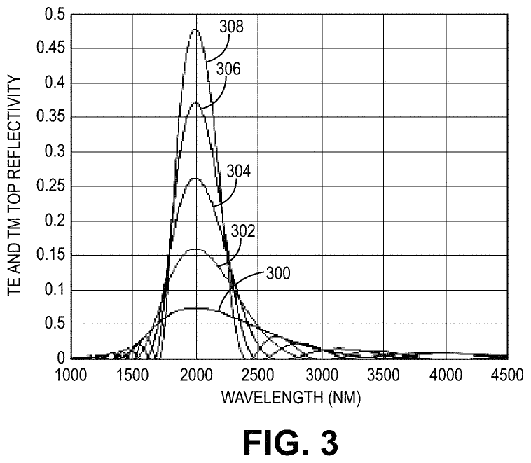

In some embodiments, reflectivity efficiency is related, at least in part, on the number of layers within the EPB layer 120 (described in more detail in FIG. 3). Increasing the number of layers typically increases the reflectivity at a cost of additional thickness associated with the EPB layer 120.

FIG. 2A is a cross-sectional view of a dual band photodetector 104 according to some embodiments. As described with respect to FIG. 1, the dual band photodetector 104 includes an anti-reflective coating 108, substrate 110, cathode contact 112, metal contact 113, interconnect contact 114, first band absorber layer 118, EPB layer 120, second band absorber layer 122, contact layer 124, top contact layer 126 and contact pad 128. As discussed with respect to FIG. 1, incident light is received via the A/R coating 108 and provided to the respective layers of the dual band photodetector. As described above, in some embodiments the first band absorber layer 118 is configured to detect a lower spectral band than the second band absorber layer 122 (i.e., first band absorber layer 118 absorbs lower wavelength, higher energy photons). Light received through the A/R coating 108 within the first spectral band is absorbed by the first band absorber layer 118. Light within a second spectral band passes through the first band absorber layer 118 and through the EPB layer 120 and is absorbed by the second band absorber layer 122. Absorption of photons by the first band absorber layer 118 or the second band absorber layer 122 results in the generation of electron-hole pairs in the respective region. During a first mode of operation, the first band absorber layer 118 is reverse biased to collect minority carrier created by the absorption of light in the first spectral range by the first band absorption layer 118. During this mode of operation, the EPB layer 120 prevents transmission of carriers created in the second band absorber layer 122 from being collected along with other carriers. During a second mode of operation, the second band absorber layer 122 is reverse biased to collect minority carriers created by the absorption of light in the second spectral range by the second band absorber layer 122. During this mode of operation, the EPB layer 120 once again prevents transmission of carriers created in the first band absorber layer 118 from being collected along with other carriers. In some embodiments, the EPB layer 120 includes at least one high bandgap layer 132 characterized by a first refractive index (shown in the magnified insert) and at least one intervening layer 134 characterized by a second refractive index different than the first refractive index. In some embodiments, the high bandgap layer 132 is characterized by a refractive index that is lower than the refractive index of the intervening layer 134. That is, the high bandgap layer 132 may be defined as having a low refractive index and the intervening layer 134 may be characterized as having a high refractive index. The high bandgap layer 132 acts to prevent the transport of majority carriers between the first band absorber layer 118 and the second band absorber layer 122. The intervening layer 134 presents a high contrast in refractive index as compared with the high bandgap layer 132. This contrast in refractive index between the respective layers 132 and 134 creates a distributed Bragg reflector (DBR) that acts to reflect light at a particular wavelength or range of wavelengths. In some embodiments, the thickness of the high bandgap layer 132 and the thickness of the intervening layer 134 are selected based on the wavelength of light to be reflected. In particular, in some embodiments the thickness of the high bandgap layer 132 and the thickness of the intervening layer 134 are selected based on the wavelength of light to be reflected and the refractive index of the material. For example, in some embodiments the thickness of the high bandgap layer 132 is selected based on the equation:

$$Layer\_thickness = \frac{λ * m}{n * 4}$$

wherein λ is the wavelength of the light to be reflected and n is the refractive index of the material the light is propagating within. m is an integer number that can be any odd number starting from 1 such as 1, 3, 5, 7, 9, etc.

In some embodiments, the thickness of the high bandgap layer 132 (which has a first refractive index) will be different than the thickness of the intervening layer 134 (which has a second refractive index). For example, the high bandgap layer 132—having a lower refractive index n₁—may be thicker than the corresponding intervening layer 134 characterized by a high refractive index n₂. However, because layer thickness may vary with multiples m of the wavelength, in some embodiments the high bandgap layer 132 may be thinner than the intervening layer 134 despite the lower refractive index. In addition, in some embodiments a plurality of layers, wherein increasing the number of layers increases the reflectivity efficiency of the EPB layer 120. In some embodiments, the DBR created by the one or more layers is selected based on the bandgap of the first band absorber layer 118 (or second band absorber layer 122), wherein the bandgap determines the wavelength of light generated via radiative recombination (referred to herein as the cutoff wavelength). Knowledge of the bandgap allows the DBR to be tuned to the wavelength of light generated via radiative recombination, thereby reflecting photons created via this process that might otherwise result in optical cross-talk between the respective first and second band absorber layers. In some embodiments, the intervening layer 134 is comprised of one or more of InP, GaAs, InGaAs, InAlAs, GaSb, InGaSb, AlGaSb, InAsSb, AlGaAsSb, and/or InGaAsSb, InGaAsP, InAlAsP.

In the energy band diagram within the device 116 shown in FIG. 2B, the energy band diagram associated with the first band absorber layer 118 is shown on the right side of the diagram, the energy band diagram associated with the second band absorber layer 122 is shown on the left side of the diagram, and the energy band diagram of the EPB layer 120 is illustrated between the first and second band absorber layers. Arrows 200 representing incident light direction are shown on the right side of the diagram. Incident light that is not absorbed by layer 118 and absorbed by the second band absorber layer 122 creates an electron-hole pair 208, 210 which are collected by the ROIC as a result of reverse biasing applied to the second band absorber layer 122. During this operation bias, the first band absorber layer 118 is still absorbing photons creating electron-hole pair 202,203. However, because the first band absorber layer 118 is not forward biased during this mode of operation the carriers associated with electron-hole pair 202, 203 are not collected. Within the first band absorber layer 118, radiative recombination between electron 202 and hole 203 creates a photon of light 204 having a wavelength near the band-gap (i.e. cutoff wavelength) of the first band absorber layer 118. In this embodiment, the photon 204 is reflected by the EPB layer 120 as shown by arrow 206 and prevented from propagating into the second band absorber layer 122. In this way, optical crosstalk between the first band absorber layer 118 and the second band absorber layer 122 is reduced and/or prevented.

FIG. 3 is a graph illustrating the calculated reflectivity of the electron-photon blocking (EPB) having a plurality of different numbers of layers or stacks according to some embodiments. For example, line 300 illustrates reflectivity efficiency associated with an EPB layer having a single stack consisting of an intervening layer 134 located between high bandgap layers 132, line 302 illustrates reflectivity efficiency with two stacks, line 304 illustrates reflectivity efficiency with three stacks, line 306 illustrates reflectivity efficiency with four stacks, and line 308 illustrates reflectivity efficiency with five stacks. As shown in FIG. 3, reflectivity efficiency improves with each additional stack added. In this embodiment, the reflectivity efficiency peaks at a design wavelength of approximately 2000 nm, and reflectivity efficiency of approximately 50% is achieved when using five stacks. In the embodiment shown in FIG. 3, the thickness of the high bandgap layers 132 and intervening layers 134 are designed to provide peak reflectivity at this wavelength—typically selected close to the cutoff wavelength (band-gap) of the spectral range of the first band absorber layer 118 at the operating temperature of the photodetector.

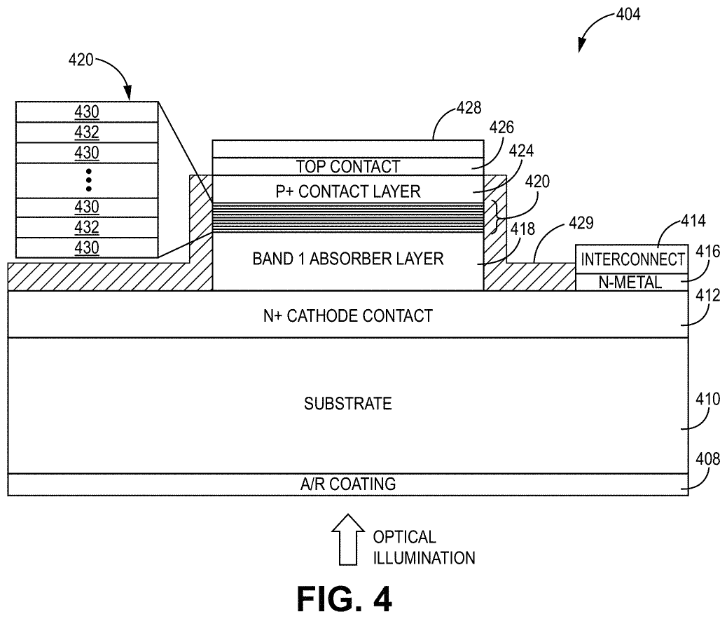

FIG. 4 is a cross-sectional view of a single band photodetector 404 according to some embodiments. Single band photodetector 404 includes an anti-reflective coating 408, substrate 410, cathode contact 412, interconnect 414, metal contact 416, first band absorber layer 418, electron-photon blocking (EPB) layer 420, contact layer 424, top contact layer 426, and contact pad 428. In contrast with the embodiment shown in FIGS. 1 and 2, the embodiment shown in FIG. 4 is a single band photodetector 404 that utilizes the EPB layer 420 to reflect light within the spectral range of the first band absorber layer 418. In this way, incident light that is not absorbed by the first band absorber layer 418 is reflected by the EPB layer 420 back toward the first band absorber layer 418 for subsequent absorption. Absorption efficiency is based in part on thickness of the first band absorber layer 418. Utilizing EPB layer 420 to reflect light a wavelength of interest by adjusting the layer widths 430, 432 in the spectral band associated with the first band absorber layer 418 allows the thickness of the first band absorber layer 418 to be decreased while maintaining the desired efficiency. In some embodiments, the EPB layer will not be able to reflect the entire absorption band of first band absorber layer 418, but can be designed to selectively reflect the wavelength of a laser or other narrower band. As shown in the magnified insert, EPB layer 420 includes at least one high band gap layer 430 and at least one intervening layer 432 to form a distribute Bragg reflector (DBR). Increasing the number of high band gap layers 430 and intervening layers 432 increases the reflectivity of the EPB layer. As described above, the thickness of the respective layers 430 and 432 is selected based on the wavelength of light to be reflected. In the embodiment shown in FIG. 4, the wavelength of light to be reflected corresponds with the wavelength of light to be absorbed by the first band absorber layer 418.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

The invention claimed is:

1. A dual band photodetector comprising:
a first band absorber layer configured to absorb incident light in a first wavelength spectral band;
a second band absorber layer configured to absorb incident light in a second wavelength spectral band; and
an electron-photon blocking (EPB) layer located between the first band absorber layer and the second band absorber layer, wherein the EPB layer includes at least one high band gap layer having a first refractive index and at least one intervening layer having a second refractive index different than the first refractive index, wherein the high band gap layer is configured to block majority carrier transport between the first band absorber layer and the second band absorber layer and a difference in refractive index between the at least one high band gap layer and the at least one intervening layer form a distributed brag reflector (DBR) designed to reflect wavelengths corresponding with radiative recombination photons emitted from at least the first absorber layer to reduce optical crosstalk between the first band absorber layer and the second band absorber layer.

2. The dual band photodetector of claim 1, wherein DBR is designed to reflect wavelengths approximately equal to a cutoff wavelength of the first absorber layer.

3. The dual band photodetector of claim 1, wherein thickness of the one or more high band gap layers and thickness of the one or more intervening layers has a thickness selected based at least in part on the wavelength of light to be reflected.

4. The dual band photodetector of claim 3, wherein the thickness of the one or more high band gap layers and the thickness of the one or more intervening layers is defined by the equation:
$$Layer\_thickness = \frac{λ * m}{n * 4}$$
wherein λ is the wavelength of the light to be reflected, n is the refractive index of the material the light is propagating within, and m is an integer number that can be any odd number starting from 1.

5. The dual band photodetector of claim 1, wherein the first wavelength spectral band is lower in wavelength than the second wavelength spectral band.

6. The dual band photodetector of claim 5, wherein the EPB reflects light in the cutoff wavelength of the first wavelength spectral band.

7. The dual band photodetector of claim 1, wherein the one or more intervening layers is comprised of a material selected from the group consisting of InP, GaAs, InGaAs, InAlAs, GaSb, InGaSb, AlGaSb, InAsSb, AlGaAsSb and/or InGaAsSb, InGaAsP, InAlAsP.

8. The dual band photodetector of claim 1, wherein the dual band photodetector is operated in a first mode in which the first band absorber layer is reverse biased to collect carriers generated by the absorption of light corresponding to the first wavelength spectral band and wherein the dual band photodetector is operated in a second mode in which the second band absorber layer is reverse biased to collect carriers generated by the absorption of light corresponding to the second wavelength spectral band.

9. A photodetector comprising:
a first band absorber layer configured to absorb incident light in a first wavelength spectral band; and
an electron-photon blocking (EPB) layer located adjacent to the first band absorber layer, wherein the EPB layer includes at least one high band gap layer having a first refractive index and at least one intervening layer having a second refractive index different than the first refractive index, wherein a difference in refractive index between the at least one high band gap layer and the at least one intervening layer form a distributed brag reflector (DBR) designed to reflect a wavelength or subset of wavelengths within the first wavelength spectral band.

10. The photodetector of claim 9, wherein thickness of the one or more high band gap layers and thickness of the one or more intervening layers has a thickness selected based at least in part on the desired wavelength of light to be reflected.

11. The photodetector of claim 10, wherein the thickness of the one or more high band gap layers and the thickness of the one or more intervening layers is defined by the equation:
$$Layer\_thickness = \frac{λ * m}{n * 4}$$
wherein λ is the wavelength of the light to be reflected, n is the refractive index of the material the light is propagating within, and m is an integer number that can be any odd number starting with 1.

12. The photodetector of claim 9, further comprising a second band absorber layer configured to absorb incident light in a second wavelength spectral band.

13. A dual band imaging device comprising:
an imaging lens;
a readout integrated circuit (ROIC); and
a dual band photodetector comprising a plurality of dual band pixels configured to receive incident light from the imaging lens and to generate an electrical response, each pixel comprising a first band absorber layer, a second band absorber layer, and a electron-photon blocking (EPB) layer located between the first band absorber layer and the second band absorber layer, wherein the EPB layer includes at least one high band gap layer and at least one intervening layer, wherein the high band gap layer is configured to block majority carrier transport between the first band absorber layer and the second band absorber layer and a difference in refractive index between the at least one high band gap layer and the at least one intervening layer form a distributed brag reflector (DBR) designed to reflect wavelengths corresponding with radiative recombination photons emitted from at least the first absorber layer to reduce optical crosstalk between the first band absorber layer and the second band absorber layer.

14. The dual band imaging device of claim 13, wherein the dual band imaging device is operated in a first mode in which the first band absorber layer is reverse biased to collect carriers generated by the absorption of light by the first band absorber layer in a first spectral band, wherein the dual band imaging device is operated in a second mode in which the second band absorber layer is reverse biased to collect carriers generated by the absorption of light by the second band absorber layer in a second spectral band, wherein during the second mode the EPB layer reflects wavelengths corresponding with radiative recombination photons emitted from the first absorber layer to reduce optical crosstalk during the second mode of operation.

15. The dual band imaging device of claim 13, wherein DBR is designed to reflect wavelengths approximately equal to a cutoff wavelength of the first absorber layer.

16. The dual band imaging device of claim 13, wherein thickness of the one or more high band gap layers and thickness of the one or more intervening layers has a thickness selected based at least in part on the wavelength of light to be reflected.

17. The dual band imaging device of claim 16, wherein the thickness of the one or more high band gap layers and the thickness of the one or more intervening layers is defined by the equation:
$$Layer\_thickness = \frac{λ * m}{n * 4}$$
wherein λ is the wavelength of the light to be reflected, n is the refractive index of the material the light is propagating within, and m is an integer number that can be any odd number starting with 1.

18. The dual band imaging device of claim 14, wherein the first spectral band is lower in wavelength than the second spectral band.
